(19) United States
(12) Patent Application Publication
(10) Pub. No.: US 2019/0013263 A1
(43) Pub. Date: Jan. 10, 2019

(54) WIRING BOARD AND SEMICONDUCTOR PACKAGE

(71) Applicant: SHINKO ELECTRIC INDUSTRIES CO., LTD., Nagano (JP)

(72) Inventors: Masahiro KYOZUKA, Nagano (JP); Takahiko KISO, Nagano (JP)

(21) Appl. No.: 16/014,110

(22) Filed: Jun. 21, 2018

(30) Foreign Application Priority Data
Jul. 6, 2017 (JP) 2017-132683

(51) Int. Cl. H01L 23/498; H01L 23/00; H05K 3/34

(52) U.S. Cl. CPC H01L 23/49822; H01L 23/49816; H01L 23/49838; H01L 2924/15311; H05K 3/3452; H01L 24/17; H01L 2224/0401; H01L 24/09

(57) ABSTRACT

A wiring board, includes a core substrate that includes first pads for mounting a semiconductor chip, second pads provided at the periphery of the first pads, and a solder resist layer that selectively exposes the first pads and the second pads; a first insulation layer, formed on the solder resist layer, including an opening to be formed in a frame shape such that to expose the first pads and cover the second pads; and external connection terminals penetrating the first insulation layer to be electrically connected to the second pads, respectively, and partially exposed from the first insulation layer, wherein the core substrate includes a second insulation layer, wherein the first pads, the second pads and the solder resist layer are directly formed on the second insulation layer, and wherein a rim of an inner wall surface of the opening at the core substrate side contacts the solder resist layer.

### CROSS-REFERENCE TO RELATED APPLICATIONS

The present application is based on and claims the benefit of priority of Japanese Priority Application No. 2017-132683 filed on Jul. 6, 2017, the entire contents of which are hereby incorporated by reference.

### FIELD

### 1. Field of the Invention

The present invention relates to a wiring board and a semiconductor package.

### 2. Description of the Related Art

Recently, electronic devices in which semiconductor packages are mounted are becoming smaller. In accordance with this, it is required for a wiring board for a semiconductor package to become smaller.

As a wiring board for a semiconductor package, for example, a structure is known that includes a core substrate and a stacked body, in which insulation layers and wiring layers are stacked, formed on the core substrate, and in which a cavity for mounting a semiconductor chip is formed at a part of the stacked body.

The cavity may be formed by, for example, forming a frame-shaped gap in a planar view at a part of the insulation layers and the wiring layers of the stacked body by using laser, and removing a part of the insulation layers and the wiring layers of the stacked body within the gap (see Patent Document 1, for example).

However, when laser is used for forming a cavity, it is necessary to form a conductive pattern for receiving the laser to protect the insulation layers, that are not removed by the laser, under the frame-shaped gap. Due to this, it is difficult to make a wiring board smaller.

### PATENT DOCUMENT

[Patent Document 1] Japanese Laid-open Patent Publication No, 2015-106615

### SUMMARY OF THE INVENTION

The present invention is made in light of the above problems, and provides a wiring board for a semiconductor package having a small size.

According to an embodiment, there is provided a wiring board, including: a core substrate that includes, at one side of the core substrate, a plurality of first pads for mounting a semiconductor chip, a plurality of second pads provided at the periphery of the first pads, and a solder resist layer that selectively exposes the first pads and the second pads; a first insulation layer, formed on an upper surface of the solder resist layer, including an opening to be formed in a frame shape such that to expose the first pads and cover the second pads; and a plurality of external connection terminals penetrating the first insulation layer to be electrically connected to the second pads exposed from the solder resist layer, respectively, and partially exposed from an upper surface of the first insulation layer, wherein the core substrate includes a second insulation layer, wherein the first pads, the second pads and the solder resist layer are directly formed on one surface of the second insulation layer, and wherein a rim of an inner wall surface of the opening at the core substrate side contacts the upper surface of the solder resist layer.

### BRIEF DESCRIPTION OF THE DRAWINGS

Other objects, features and advantages of the present invention will become more apparent from the following detailed description when read in conjunction with the accompanying drawings.

FIG. 1A and FIG. 1B are views illustrating an example of a wiring board of a first embodiment;

FIG. 2A to FIG. 2D are views illustrating a manufacturing step of the wiring board of the first embodiment;

FIG. 3A to FIG. 3D are views illustrating the manufacturing step of the wiring board of the first embodiment;

FIG. 4A and FIG. 4B are views illustrating a manufacturing step of a wiring board of a comparative example;

FIG. 5A to FIG. 5D are views illustrating the manufacturing step of the wiring board of the comparative example;

FIG. 6A and FIG. 6B are views illustrating the manufacturing step of the wiring board of the comparative example;

FIG. 7A to FIG. 7D are views illustrating a manufacturing step of a wiring board of a modified example 1 of the first embodiment;

FIG. 8A and FIG. 8B are views illustrating an example of a semiconductor package of a second embodiment; and

FIG. 9A to FIG. 9C are views illustrating a manufacturing step of the semiconductor package of the second embodiment.

### DETAILED DESCRIPTION

The invention will be described herein with reference to illustrative embodiments. Those skilled in the art will recognize that many alternative embodiments can be accomplished using the teachings of the present invention and that the invention is not limited to the embodiments illustrated for explanatory purposes.

It is to be noted that, in the explanation of the drawings, the same components are given the same reference numerals, and explanations are not repeated.

### First Embodiment

### (Structure of Wiring Board of First Embodiment)

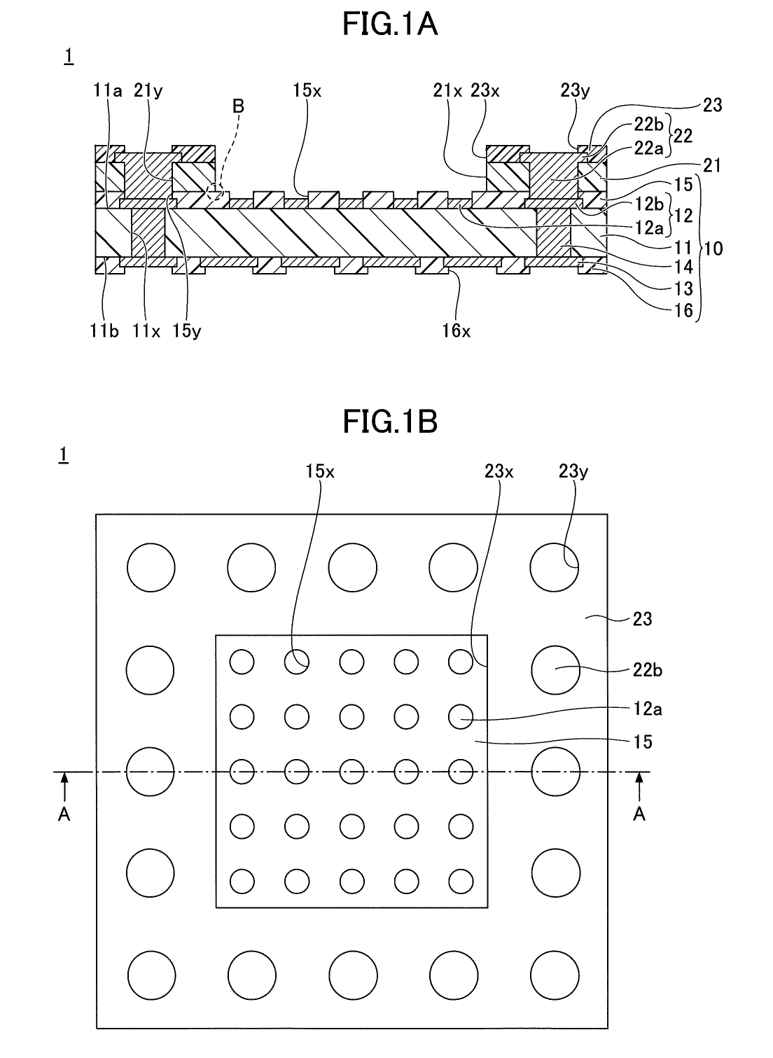

First, a structure of a wiring board of a first embodiment is described. FIG. 1A and FIG. 1B are views illustrating an example of a wiring board 1 of a first embodiment, wherein FIG. 1B is a plan view, and FIG. 1A is a cross-sectional view taken along an A-A line of FIG. 1B.

With reference to FIG. 1, the wiring board 1 of the first embodiment includes a core substrate 10, a first insulation layer 21, external connection terminals 22 and a solder resist layer 23. The core substrate 10 includes a second insulation layer 11, wiring layers 12 and 13, through wirings 14 and solder resist layers 15 and 16.

In the following explanation, a solder resist layer 23 side of the wiring board 1 is referred to as one side or an upper side, and a solder resist layer 16 of the wiring board 1 is referred to as the other side or a lower side. Further, a surface of each component at the solder resist layer 23 side is referred to as one surface or an upper surface, and a surface of each component at the solder resist layer 16 side is referred to as the other surface or a lower surface. However, the wiring board 1 may be used in an opposite direction or may be used at a desired angle. Further, in this embodiment, “in a planar view” means that an object is seen in a direction that is normal to one surface 11a of the second insulation layer 11, and a “planar shape” means a shape of an object seen in the direction that is normal to the one surface 11a of the second insulation layer 11.

Hereinafter, each component of the wiring board 1 is described in detail. Although the wiring board 1 has a rectangular planar shape in an example of FIG. 1, it is not limited so, and the wiring board 1 may have any desired planar shape.

The core substrate 10 is a base portion for forming other layers. In the example of FIG. 1, the core substrate 10 is a 2-layer wiring board including the two wiring layers 12 and 13. Alternatively, the core substrate 10 may be a multilayer wiring board such as a build-up wiring board, for example, that further includes another wiring layer (inner layer) in the second insulation layer 11.

The second insulation layer 11 may be formed by photosensitive insulation resin (thermosetting resin, for example) whose main constituent is epoxy-based resin, phenol-based resin, polyimide-based resin, cyanate-based resin or the like, for example. Alternatively, the second insulation layer 11 may be formed by non-photosensitive insulation resin (for example, thermosetting resin) whose main constituent is epoxy-based resin, phenol-based resin, polyimide-based resin, cyanate-based resin or the like, for example. Further, the second insulation layer 11 may include a reinforce member such as a glass cloth. Further, the second insulation layer 11 may include a woven fabric or a nonwoven fabric such as glass fiber, carbon fiber or aramid fiber, as the reinforce member. Further, the second insulation layer 11 may include fillers such as silica or alumina. The thickness of the second insulation layer 11 may be appropriately determined in accordance with a required property, and for example, may be approximately 70 to 400 μm.

A plurality of through holes 11x are formed in the second insulation layer 11. Each of the through holes 11x may have a circular planar shape, for example. Through wirings 14 are formed in the through holes 11x, respectively. As a material of the through wiring 14, for example, copper (Cu) or the like may be used.

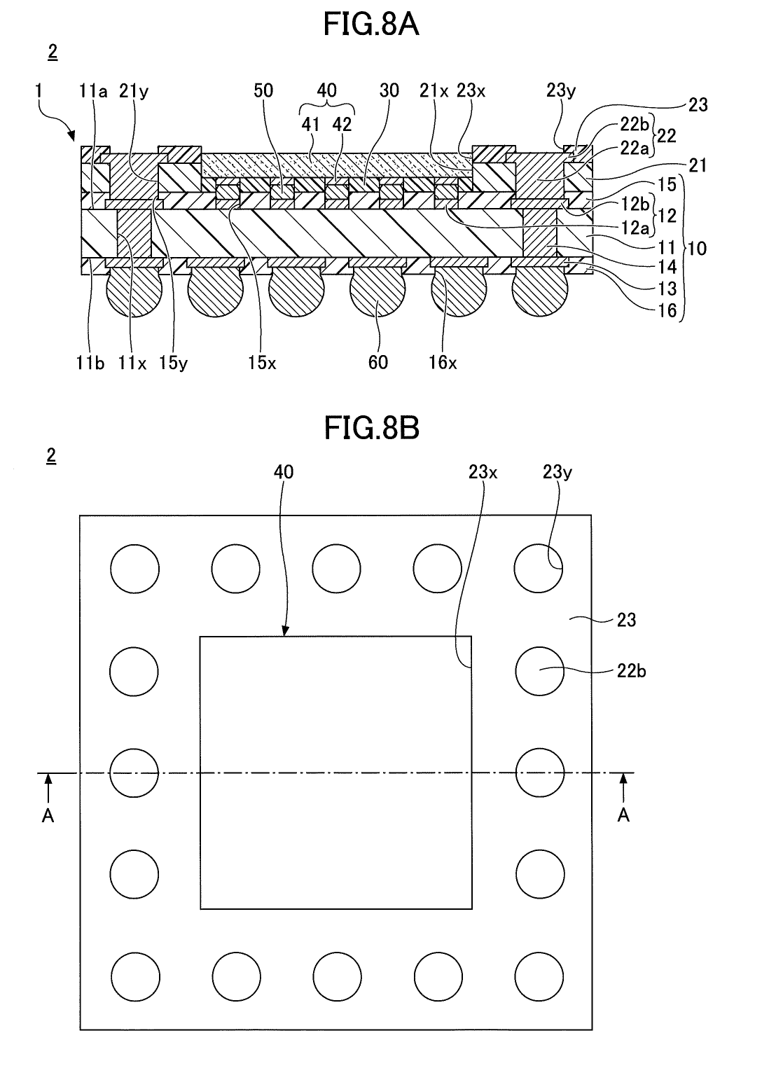

The wiring layer 12 is formed at the one surface 11a of the second insulation layer 11. The wiring layer 12 includes first pads 12a and second pads 12b. The first pads 12a are provided for mounting a semiconductor chip when manufacturing a semiconductor package (see FIG. 8, which will be described later) in which the semiconductor chip is mounted on the wiring board 1. The external connection terminals 22 are formed on the second pads 12b, respectively. The second pads 12b are provided at the periphery of the first pads 12a, for example.

As the first pads 12a are electrically connected to a semiconductor chip, the first pads 12a are finely formed, and each of which may have a circular shape with a diameter of approximately 30 μm in a planar view, for example. A pitch of the adjacent first pads 12a may be approximately 40 μm, for example. The first pads 12a may be aligned in an area array form. Each of the second pads 12b may have a circular shape with a diameter of approximately 110 μm in a planar view, for example. A pitch of the adjacent second pads 12b may be approximately 150 μm, for example. A pitch between the adjacent first pads 12a may be smaller than a pitch between the adjacent second pads 12b.

The wiring layer 13 is formed at the other surface 11b of the second insulation layer 11. The wiring layer 12 and the wiring layer 13 may be appropriately electrically connected with each other via the through wirings 14, respectively. Specifically, the first pads 12a and the second pads 12b are electrically connected to wiring patterns of the wiring layer 13 via the through wirings 14, respectively. As a material of each of the wiring layers 12 and 13, for example, copper (Cu) or the like may be used. Each of the wiring layers 12 and 13 may be a stacked structure of a plurality of metal layers. The thickness of each of the wiring layers 12 and 13 may be, for example, approximately 15 to 35 μm.

The solder resist layer 15 is an insulation member formed at the one surface 11a of the second insulation layer 11 such that to cover the wiring layer 12. The solder resist layer 15 selectively exposes the first pads 12a and the second pads 12b. Specifically, the solder resist layer 15 includes openings 15x and an upper surface of each of the first pads 12a is exposed in the respective opening 15x. Further, the solder resist layer 15 includes openings 15y, and an upper surface of each of the second pads 12b is exposed in the respective opening 15y.

A surface processing layer (not illustrated) may be formed on the upper surface of each of the first pads 12a exposed in the respective opening 15x or on the upper surface of each of the second pads 12b exposed in the respective opening 15y. As an example of the surface processing layer, an Au layer, a Ni/Au layer (a metal layer including a Ni layer and an Au layer stacked in this order), a Ni/Pd/Au layer (a metal layer including a Ni layer, a Pd layer and an Au layer stacked in this order) or the like may be used. Further, the surface processing layer may be formed by performing an antioxidation process such as an Organic Solderability Preservative (OSP) process to the upper surface of each of the first pads 12a exposed in the respective opening 15x or to the upper surface of each of the second pads 12b exposed in the respective opening 15y. When the OSP process is performed, an organic film made of an azole compound, an imidazole compound or the like is formed as the surface processing layer, for example.

The solder resist layer 16 is formed at the other surface 11b of the second insulation layer 11 such that to cover the wiring layer 13. The solder resist layer 16 includes openings 16x, and a lower surface of the wiring layer 13 is exposed in each of the openings 16x. The surface processing layer (not illustrated) as described above may be formed on the lower surface of the wiring layer 13 exposed in each of the openings 16x.

As a material of each of the solder resist layers 15 and 16, photosensitive insulation resin (thermosetting resin, for example) whose main constituent is epoxy-based resin, phenol-based resin, polyimide-based resin or the like may be used, for example. Each of the solder resist layers 15 and 16 may include fillers such as silica or alumina.

The solder resist layer 15 may be provided to cover the outer periphery of each of the first pads 12a and the second pads 12b and expose only a center portion of each of the first pads 12a and the second pads 12b. Alternatively, the solder resist layer 15 may be provided to expose the entirety of each of the first pads 12a and the second pads 12b. When the entirety of each of the first pads 12a and the second pads 12b is exposed, the solder resist layer 15 may be provided such that a side surface of each of the first pads 12a and the second pads 12b and a side surface of the solder resist layer 15 (an inner wall surface of the respective opening) contact. Alternatively, the solder resist layer 15 may be provided such that a space is formed between the side surface of each of the first pads 12a and the second pads 12b and the side surface of the solder resist layer 15 (the inner wall surface of the respective opening). Each of the solder resist layer 16 and the solder resist layer 23 is similarly provided.

The first insulation layer 21 has a frame shape and is formed at the periphery of the upper surface of the solder resist layer 15 that constitutes the core substrate 10. The first insulation layer 21 may be formed by insulation resin similarly as the second insulation layer 11, for example. The first insulation layer 21 may include the reinforce member or the fillers similarly as the second insulation layer 11, for example. The thickness of the first insulation layer 21 may be appropriately determined in accordance with a required property, and for example, may be approximately 50 to 160 μm.

An opening 21x (a cavity) that exposes the upper surface of the solder resist layer 15 and the upper surface of each of the first pads 12a is formed in the first insulation layer 21. In other words, the first insulation layer 21 is formed to have a frame shape such that to surround the opening 21x. The opening 21x may have a rectangular planar shape, for example.

A rim of the inner wall surface of the opening 21x at the core substrate 10 side contacts the upper surface of the solder resist layer 15 (portion “B” of FIG. 1A). In other words, a bottom edge of the inner wall surface of the first insulation layer 21 around the opening 21x contacts the upper surface of the solder resist layer 15. Here, a portion of the solder resist layer 15 that contacts the rim of the inner wall surface of the opening 21x at the core substrate 10 is directly formed on the one surface 11a of the second insulation layer 11, and does not cover a conductive pattern and the like (a lower side of the portion “B” of FIG. 1A). Here, alternatively, the solder resist layer 15 may not be formed, and when the solder resist layer 15 is not formed, the rim of the inner wall surface of the opening 21x at the core substrate 10 side contacts the one surface 11a of the second insulation layer 11. As such, the rim of the inner wall surface of the opening 21x at the core substrate 10 side always contacts an insulation member, and does not contact the wiring layer 12 or other conductive member such as the conductive pattern and the like.

Openings 21y are formed in the first insulation layer 21 that communicate with the openings 15y of the solder resist layer 15, respectively. The upper surface of each of the second pads 12b is exposed in the respective opening 21y. The opening 21y may have a circular planar shape having a size same as that of the opening 15y, for example.

Each of the external connection terminals 22 is formed on the upper surface of the respective second pad 12b that is exposed in the respective opening 15y and the opening 21y. Each of the external connection terminal 22 includes a via wiring 22a that fills the respective openings 15y and 21y, and a pad 22b that is integrally formed with the respective via wiring 22a and extends over the upper surface of the first insulation layer 21 around the opening 21y. In other words, the external connection terminal 22 penetrates the first insulation layer 21 to be electrically connected with the second pad 12b, and is partially exposed from the upper surface of the first insulation layer 21. As a material of the external connection terminal 22, for example, copper (Cu) or the like may be used. The thickness of the pad 22b that constitutes the external connection terminal 22 may be approximately 10 to 25 μm, for example.

The solder resist layer 23 is formed on the upper surface of the first insulation layer 21. The solder resist layer 23 includes an opening 23x that communicates with the opening 21x of the first insulation layer 21. The upper surface of the solder resist layer 15 and the upper surface of each of the first pads 12a are exposed in the opening 23x. The opening 23x may have a rectangular planar shape having a size same as that of the opening 21x, for example. The solder resist layer 23 further includes openings 23y, and an upper surface of each of the pads 22b is exposed in the opening 23y. Each of the openings 23y may have a circular planar shape, for example. The surface processing layer (not illustrated) as described above may be formed on the upper surface of the pad 22b exposed in the opening 23y.

The pads 22b exposed in the openings 23y, respectively, may be provided in a peripheral form around the opening 23x (a region at which a semiconductor chip is mounted) in a planar view, for example. The pads 22b may be aligned in a plurality of rows. The pads 22b may be used as so-called POP pads (pads of Package On Package) that are electrically connected with a semiconductor package.

### (Method of Manufacturing Wiring Board of First Embodiment)

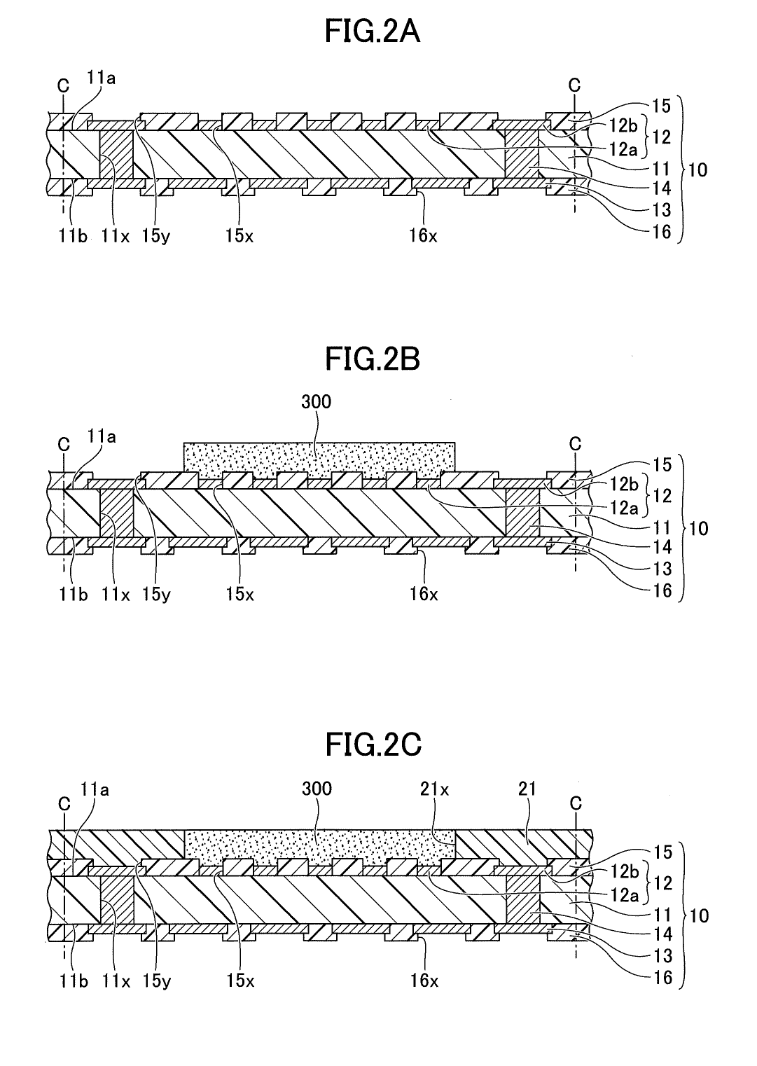

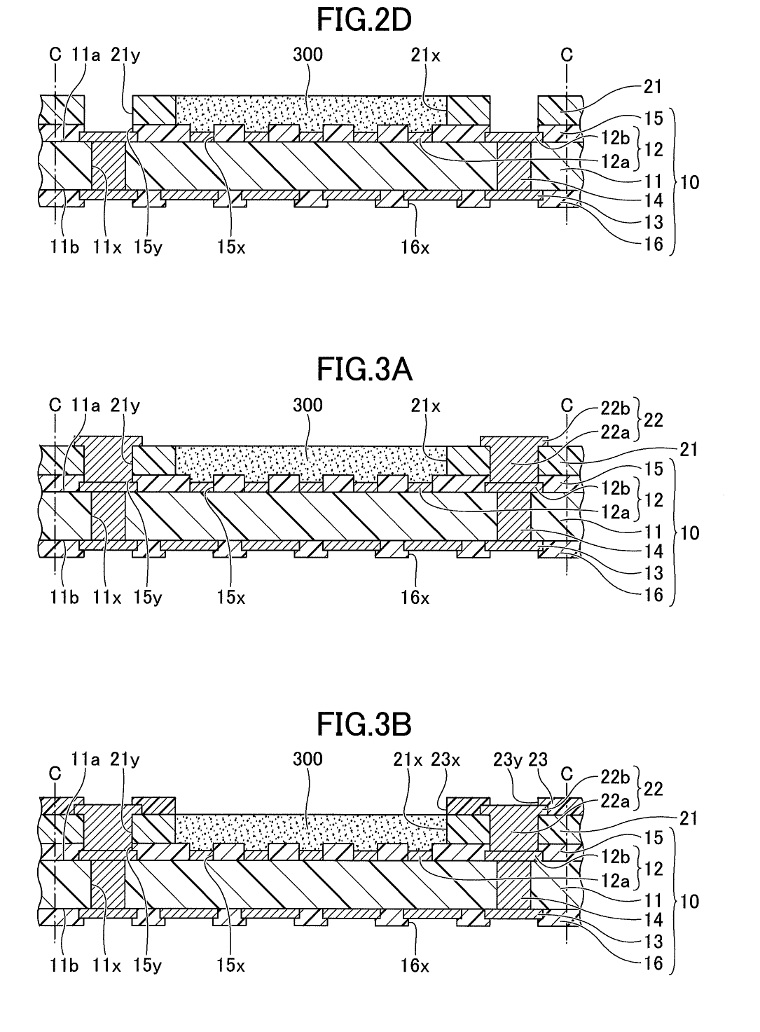

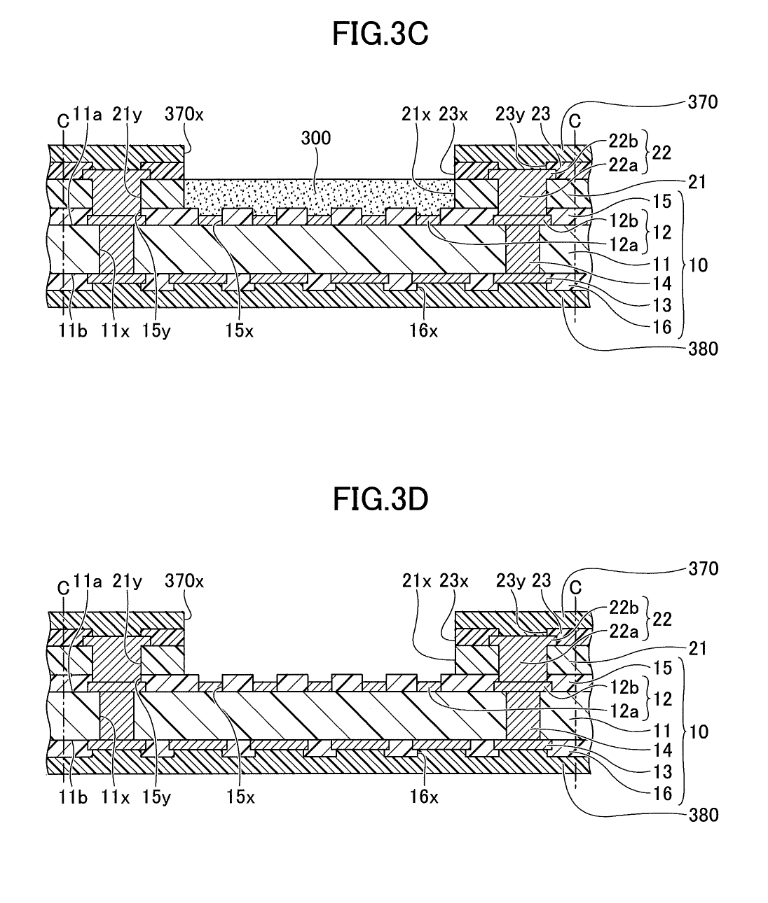

Next, a method of manufacturing the wiring board of the first embodiment is described. FIG. 2A to FIG. 3D are views illustrating an example of a manufacturing step of the wiring board 1 of the first embodiment. Although an example of a manufacturing step is described in this embodiment in which a part corresponding to a plurality of wiring boards is firstly manufactured and then, the plurality of wiring boards are obtained by individualizing the part, a manufacturing step in which each single wiring board is manufactured may be alternatively used.

First, in a step illustrated in FIG. 2A, the core substrate 10 is manufactured by a known method. For example, the through holes 11x are formed in the second insulation layer 11 by laser processing or drilling, and the through wirings 14 are formed by filling a conductive material such as copper in the through holes 11x, respectively, by electroless plating, electrolytic plating and the like. Then, for example, the wiring layer 12 is selectively formed at the one surface 11a of the second insulation layer 11 and the wiring layer 13 is selectively formed at the other surface 11b of the second insulation layer 11 by various methods of forming a wiring such as a subtractive method or a semi-additive method.

Then, for example, photosensitive resin is coated or laminated at the one surface 11a of the second insulation layer 11, and the solder resist layer 15 including the openings 15x and 15y is formed by exposing and developing the photosensitive resin. Similarly, for example, photosensitive resin is coated or laminated at the other surface 11b of the second insulation layer 11, and the solder resist layer 16 including the openings 16x are formed by exposing and developing the photosensitive resin.

Here, chain lines “C” indicate cutting positions when manufacturing a plurality of individualized wiring boards. In other words, a region between the cutting positions “C” finally becomes the individualized wiring board 1.

Next, in a step illustrated in FIG. 2B, a protection layer 300, that covers the first pads 12a and exposes the second pads 12b, is formed at the one side of the core substrate 10. It is preferable that the planar shape and the thickness of the protection layer 300 are the same as those of a semiconductor chip, which will be mounted on the wiring board 1 in a post-process. As the protection layer 300, for example, a material is selected that has heat-resistance greater than or equal to heating temperature (approximately 200° C. to 300° C., for example) in a heating step included in the post-process, and also that is soluble to specific liquid even after being cured. The specific liquid is constituted not to solve the metal forming the first pads 12a but is capable of solving only the protection layer 300.

The protection layer 300 may include an adhesive layer that covers the first pads 12a. In this embodiment, as an example, the protection layer 300 is formed only by the adhesive layer. As the protection layer 300 (=adhesive layer), for example, a polyester-based resin film or a polyvinyl alcohol-based resin film may be used.

For forming the protection layer 300, for example, a semi-cured protection layer 300 is prepared, and then the semi-cured protection layer 300 is mounted to cover the first pads 12a at the region (region between the cutting positions “C”) that becomes the wiring board 1 by using a chip mounter. Then, the protection layer 300 is heated to predetermined temperature to be cured while pressing the protection layer 300 toward the core substrate 10, for example.

By forming the protection layer 300, for example, when heating the first insulation layer 21 to be cured in a step of FIG. 2C, the first pads 12a are prevented from being mechanically damaged (thermal stress or the like) or chemically damaged (thermal oxidation or the like) by heating. Further, by forming the protection layer 300, for example, when removing a seed layer by etching in a step of FIG. 3A, the first pads 12a are prevented from being chemically damaged (corrosion or the like).

Next, in the step illustrated in FIG. 2C, the first insulation layer 21 is formed on the upper surface of the solder resist layer 15 that are positioned at the periphery of the protection layer 300 in a frame shape such that to cover the second pads 12b. The first insulation layer 21 may be formed by, for example, laminating an insulation resin film, in which the rectangular opening 21x is previously formed, at the periphery of the upper surface of the solder resist layer 15 such that to expose the upper surface of the protection layer 300, and heating up to predetermined temperature to cure. Alternatively, the first insulation layer 21 may be formed by coating liquid or paste insulation resin and curing it. Here, residue of the resin included in the first insulation layer 21 may be adhered at the upper surface of the protection layer 300.

The first insulation layer 21 is formed to cover at least a part of the side surface of the protection layer 300 at the core substrate 10 side and the second pads 12b, and to expose the upper surface of the protection layer 300. At this time, the upper surface of the protection layer 300 may protrude from an upper surface of the first insulation layer 21. Alternatively, the first insulation layer 21 may be formed to cover the entirety of the side surface of the protection layer 300, and may be formed such that the upper surface of the first insulation layer 21 protrudes from the upper surface of the protection layer 300. Alternatively, the first insulation layer 21 may be formed to cover the entirety of the side surface of the protection layer 300, and may be formed such that the upper surface of the first insulation layer 21 and the upper surface of the protection layer 300 are substantially flush with each other.

Next, in a step illustrated in FIG. 2D, the openings 21y that expose the upper surfaces of the second pads 12b by communicating with the openings 15y are formed, respectively. The openings 21y may be, for example, formed by laser processing.

Next, in a step illustrated in FIG. 3A, the external connection terminals 22 are formed on the upper surfaces of the second pads 12b exposed in the openings 15y and the openings 21y, respectively. In other words, the external connection terminals 22 that penetrate the first insulation layer 21, are electrically connected to the second pads 12b, respectively, and partially exposed from the upper surface of the first insulation layer 21 are formed. For forming the external connection terminals 22, for example, a seed layer (not illustrated) made of copper or the like is continuously formed over the upper surface of the protection layer 300, the upper surface of the first insulation layer 21, inner wall surfaces of the openings 15y and 21y and the upper surfaces of the second pads 12b exposed in the openings 15y and 21y, respectively, by electroless plating or sputtering. Further, a resist layer (not illustrated) having openings corresponding to shapes of the pads 22b of the external connection terminals 22, respectively, is formed on the seed layer. Then, by electrolytic plating using the seed layer as a power supply layer, an electrolytic plating layer made of copper (Cu) or the like (not illustrated) is formed in the openings 15y and 21y and the openings of the resist layer.

Subsequently, after removing the resist layer, the seed layer that is not covered by the electrolytic plating layer is removed by etching using the electrolytic plating layer as a mask. With this, the external connection terminals 22 each including the via wiring 22a filled in the openings 15y and 21y, and the pad 22b integrally formed with the respective via wiring 22a and extended at the upper surface of the first insulation layer 21 at the periphery of the opening 21y are formed. Here, in this case, the external connection terminal 22 has a structure in which the electrolytic plating layer is stacked on the seed layer. However, in each of the drawings, the seed layer is not illustrated.

Next, in a step illustrated in FIG. 3B, the solder resist layer 23 is formed. For forming the solder resist layer 23, for example, liquid or paste insulation resin is coated by screen printing, roll coating, spin coating or the like to cover the upper surface of the protection layer 300, the upper surface of the first insulation layer 21 and the upper surface and the side surface of each of the pads 22b. Alternatively, an insulation resin film may be laminated to cover the upper surface of the protection layer 300, the upper surface of the first insulation layer 21, and the upper surface and the side surface of each of the pads 22b. Then, by exposing and developing the coated or laminated insulation resin, the opening 23x that exposes the upper surface of the protection layer 300 by communicating with the opening 21x of the first insulation layer 21, and the openings 23y that expose the upper surfaces of the pads 22b, respectively, are formed in the solder resist layer 23 (photolithography).

Next, in a step illustrated in FIG. 3C, resist layers 370 and 380 that cover a portion other than the protection layer 300 are formed. Specifically, first, the resist layer 370 is formed by laminating dry film resist, for example, to cover the upper surface of the solder resist layer 23 and the upper surfaces of the pads 22b exposed in the openings 23y, respectively, such that the upper surface of the protection layer 300 is exposed in the opening 23x. Further, the resist layer 380 is formed by laminating dry film resist, for example, to cover the lower surface of the solder resist layer 16 and the lower surface of the wiring layer 13 exposed in the openings 16x.

Next, in a step illustrated in FIG. 3D, the protection layer 300 is removed. For example, when a polyester-based film material is used as the protection layer 300, the protection layer 300 can be removed by solvent such as ketone, acetone or trimethylanilinium hydroxide. At this time, when the first pads 12a are constituted by copper, as the copper does not dissolve by solvent such as ketone, acetone or trimethylanilinium hydroxide, the first pads 12a are not damaged by the solvent. Here, by removing the protection layer 300, the opening 21x having a frame shape that exposes the first pads 12a are formed in the first insulation layer 21, and the rim of the inner wall surface of the opening 21x at the core substrate 10 side contacts the upper surface of the solder resist layer 15.

After the step illustrated in FIG. 3D, by cutting the structure illustrated in FIG. 3D by a slicer and the like at the cut positions “C”, the plurality of individualized wiring boards 1 (see FIG. 1) are completed.

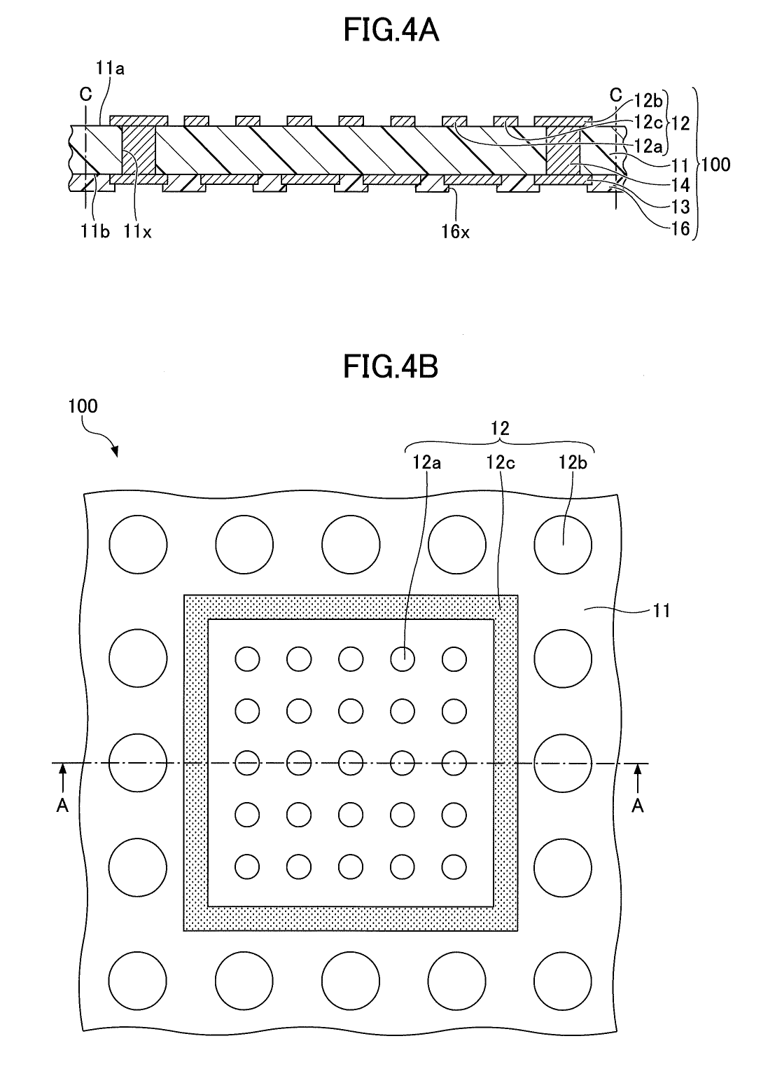

Next, specific effects of the wiring board 1 are described by comparing with the comparative example. FIG. 4 to FIG. 6 are views illustrating a manufacturing step of the wiring board of the comparative example. First, a core substrate 100 illustrated in FIG. 4A and FIG. 4B is prepared. The core substrate 100 is different from the core substrate 10 (see FIG. 2A) in that the wiring layer 12 further includes a conductive pattern 12c in addition to the first pads 12a and the second pads 12b, and the solder resist layer 15 is not formed. The conductive pattern 12c is formed to have a frame shape in a planar view such that to surround the first pads 12a. Here, in FIG. 4B, the conductive pattern 12c is illustrated by a dotted pattern.

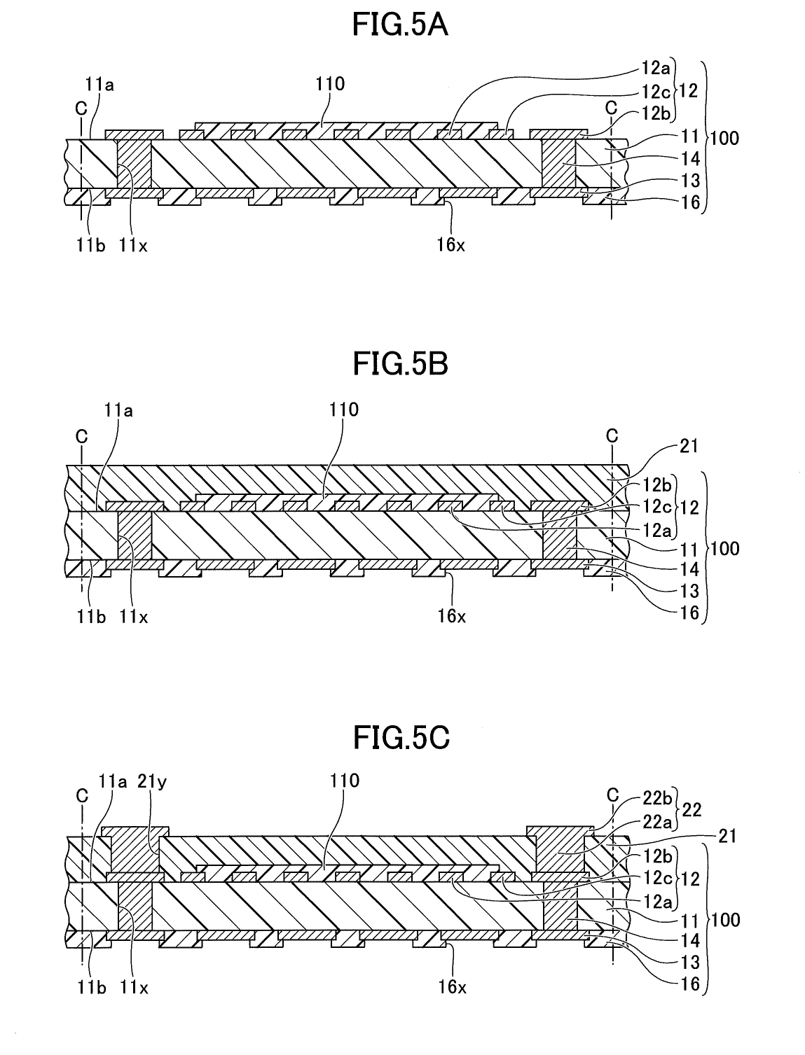

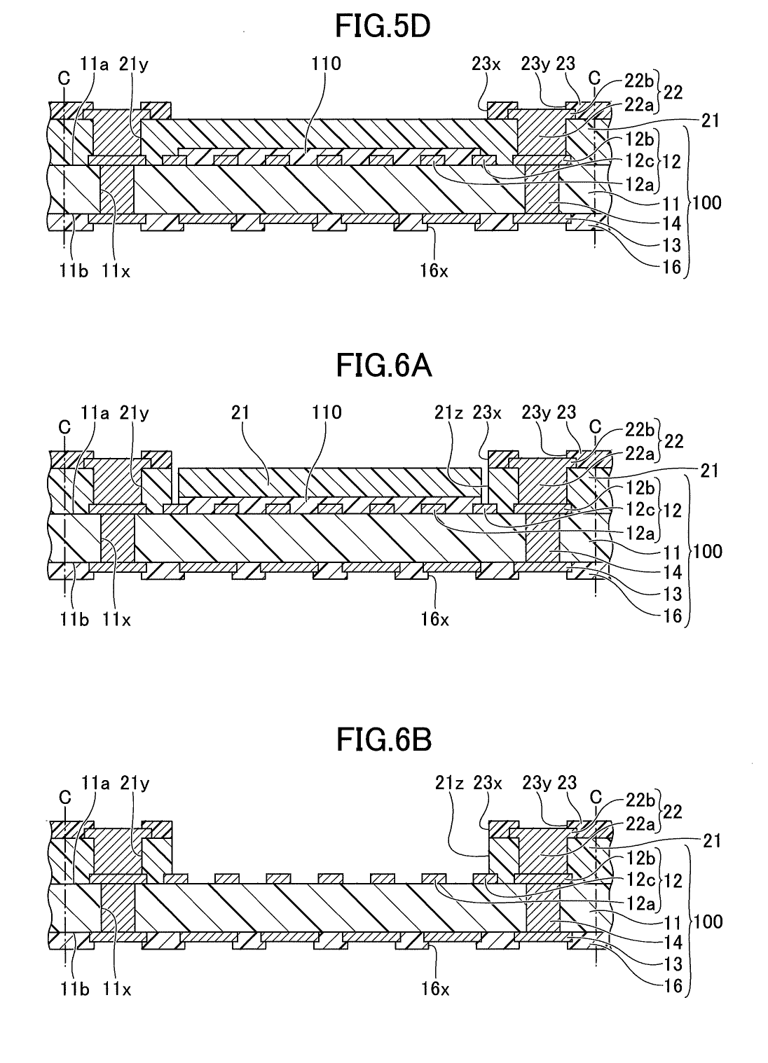

Next, as illustrated in FIG. 5A, a peeling layer 110 having a rectangular planar shape is formed on the upper surface 11a of the second insulation layer 11 to cover the entirety of the first pads 12a and an inner side surface of the conductive pattern 12c and expose the outer periphery of the conductive pattern 12c and the second pads 12b. Then, as illustrated in FIG. 5B, a first insulation layer 21 is formed at the upper surface 11a of the second insulation layer 11 to cover the peeling layer 110, the outer periphery side of the conductive pattern 12c and the second pads 12b.

Next, as illustrated in FIG. 5C, openings 21y are formed in the first insulation layer 21, and external connection terminals 22 each including a via wiring 22a that fills the opening 21y and a pad 22b integrally formed with the via wiring 22a and extending over the upper surface of the first insulation layer 21 around the opening 21y are formed.

Next, as illustrated in FIG. 5D, the solder resist layer 23 including an opening 23x that expose the upper surface of the first insulation layer 21 and openings 23y that expose the upper surface of the pads 22b is formed. The opening 23x is formed to have a rectangular shape that is substantially the same shape as that of the upper surface of the peeling layer 110 in a planar view to expose the upper surface of the first insulation layer 21 that covers the upper surface of the peeling layer 110.

Next, as illustrated in FIG. 6A, the first insulation layer 21 and the peeling layer 110 on the conductive pattern 12c are removed by irradiating laser light from the upper surface of the first insulation layer 21 side, and a frame shaped gap 21z that reaches the upper surface of the conductive pattern 12c is formed. The entirety of the peeling layer 110 is positioned within the gap 21z. Then, as illustrated in FIG. 6B, the first insulation layer 21 and the peeling layer 110 positioned within the gap 21z are removed.

With this, a cavity that exposes the first pads 12a is formed inside the gap 21z, a rim of the inner wall surface of the cavity at the core substrate 100 side contacts the upper surface of the conductive pattern 12c. The semiconductor chip is flip-chip mounted at a region in the cavity.

As such, according to the method of manufacturing the wiring board of the comparative example, as laser light is used to form the cavity, the frame shaped conductive pattern 12c is previously formed at a position at which the laser light is irradiated in order not to damage the second insulation layer 11. If the conductive pattern 12c is not provided, a concave portion or the like is formed in the second insulation layer 11 at a position at which the laser light is irradiated, and the upper surface of the second insulation layer 11 does not become flat. In order to prevent such a damage to the second insulation layer 11, it is necessary to retain a region for forming the conductive pattern 12c, and the size of the wiring board in a lateral direction (a direction perpendicular to a stacking direction) becomes large.

On the other hand, according to the wiring board 1 of the first embodiment, as laser is not used for forming the cavity, it is unnecessary to provide a pattern corresponding to the conductive pattern 12c. Thus, it is unnecessary to retain a region for forming the pattern corresponding to the conductive pattern 12c, and the wiring board can be made smaller.

Here, in the wiring board 1, a portion of the upper surface of the insulation member (solder resist layer 15 and the like) of the core substrate 10 that contacts the rim of the inner wall surface of the opening 21x at the core substrate 10 side is flat (concave portion or the like is not formed). In other words, the entirety of the upper surface of the insulation member (solder resist layer 15 and the like) of the core substrate 10 is flat.

### Modified Example 1 of First Embodiment

In a modified example 1 of the first embodiment, an example is described in which a protection layer is provided that has a structure different from that of the first embodiment. Here, it is to be noted that, in the explanation of the drawings, components same as those described in the above first embodiment are given the same reference numerals, and explanations are not repeated.

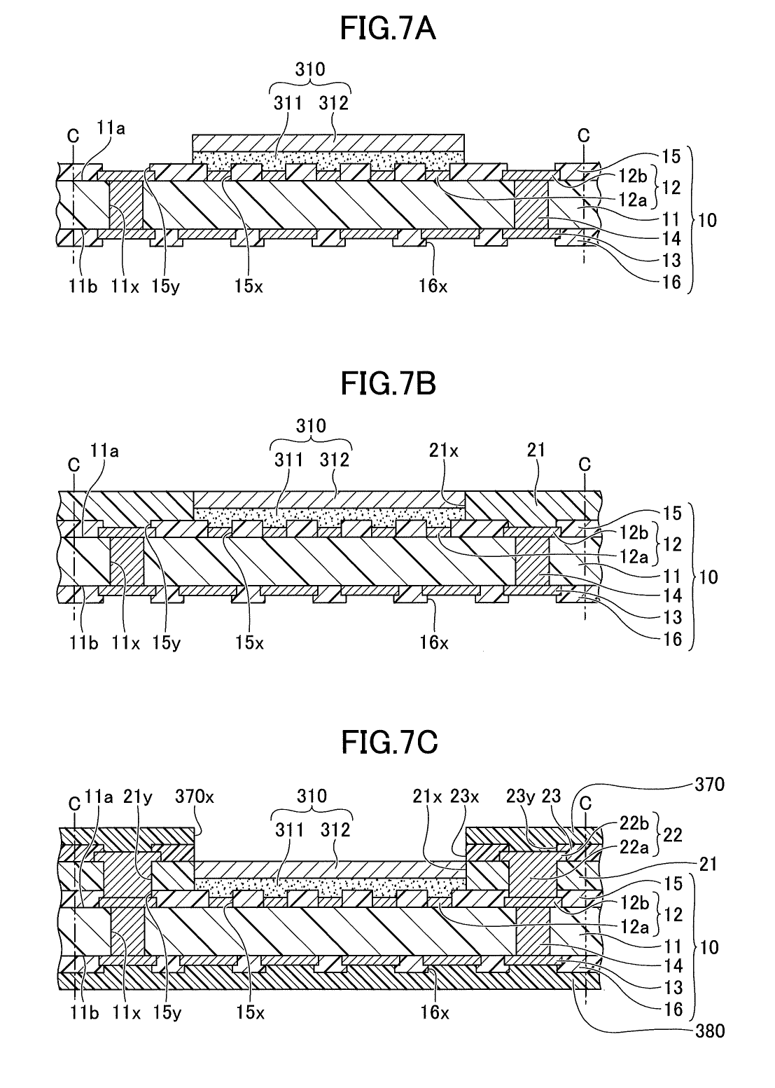

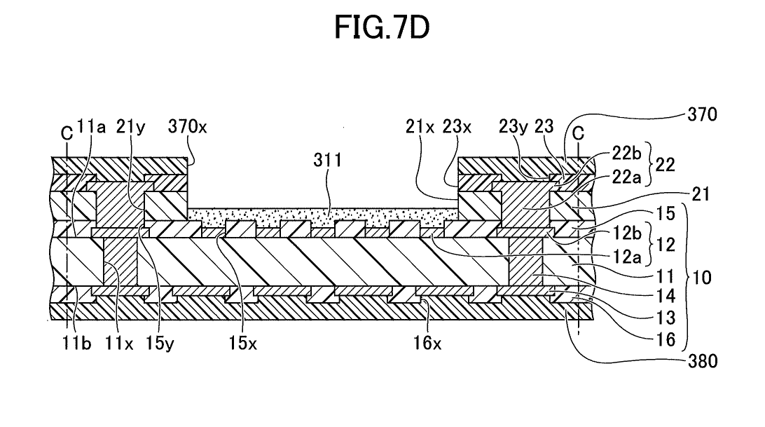

FIG. 7A to FIG. 7D are views illustrating an example of a manufacturing step of the wiring board of a modified example 1 of the first embodiment. Instead of the steps illustrated in FIG. 2A to FIG. 3C of the first embodiment, steps of FIG. 7A to FIG. 7D may be used. First, in a step illustrated in FIG. 7A, a protection layer 310 for protecting the first pads 12a for connecting a semiconductor chip is formed. The protection layer 310 may be, for example, a stacked structure of an adhesive layer 311 that covers the first pads 12a and a metal layer 312 provided on the adhesive layer 311. It is preferable that the planar shape and the thickness of the protection layer 310 are the same as those of a semiconductor chip that is mounted in a post-process.

As the adhesive layer 311, for example, a material is selected that has the heat-resistance greater than or equal to heating temperature (approximately 200° C. to 300° C., for example) in a heating step included in the post-process, and also is soluble to specific liquid even after being cured. As the adhesive layer 311, for example, a polyester-based resin film may be used. As the metal layer 312, for example, copper, aluminum, iron and the like may be used.

For forming the protection layer 310, first, a stacked body in which the metal layer 312 is stacked on the adhesive layer 311 in an uncured film form is manufactured, the stacked body is previously cut into a predetermined shape capable of covering the first pads 12a, and a plurality of such protection layers 310 are formed. Then, for example, the protection layer 310 is mounted to cover the first pads 12a at the region (region between the cutting positions “C”) that becomes the wiring board 1 by using a chip mounter. Then, the protection layer 310 is heated to predetermined temperature to be cured while pressing the protection layer 310 toward the core substrate 10, for example.

Next, in a step illustrated in FIG. 7B, similar to the step illustrated in FIG. 2C, the frame shaped first insulation layer 21 is formed on the upper surface of the solder resist layer 15 at the periphery of the protection layer 310 such that to cover the second pads 12b. Here, residue of the resin included in the first insulation layer 21 may be adhered at the upper surface of the metal layer 312 of the protection layer 310.

Next, in a step illustrated in FIG. 7C, similar to the step illustrated in FIG. 2D to FIG. 3A, the openings 21y that expose the upper surfaces of the second pads 12b by communicating with the openings 15y, respectively, are formed, and the external connection terminals 22 are formed on the upper surfaces of the second pads 12b exposed in the openings 15y and the openings 21y, respectively. Then, similar to the step illustrated in FIG. 3B, the solder resist layer 23 that includes the opening 23x that exposes the upper surface of the protection layer 310 that communicates with the opening 21x of the first insulation layer 21 and the openings 23y that expose the upper surfaces of the pads 22b, respectively, are formed. Further, similar to the step illustrated in FIG. 3C, the resist layers 370 and 380 that protect parts other than the protection layer 310 are formed.

Next, in a step illustrated in FIG. 7D, the metal layer 312 of the protection layer 310 is removed. For removing the metal layer 312, for example, after removing the residue of the resin included in the first insulation layer 21 adhered at the upper surface of the metal layer 312 by sandblasting, plasma or the like, the metal layer 312 is removed by etching. Here, the reason for removing the residue of the resin included in the first insulation layer 21 is to increase a contacting area between etching solution and the metal layer 312. For example, when the metal layer 312 is formed by copper, the metal layer 312 can be removed by wet-etching using ferric chloride aqueous solution, cupric chloride aqueous solution, ammonium persulfate aqueous solution or the like is used. Here, the adhesive layer 311 is not dissolved in the etching solution of the metal layer 312.

After the step illustrated in FIG. 7D, similar to the step illustrated in FIG. 3D, the adhesive layer 311 is removed from the structure illustrated in FIG. 7D, and the structure is cut at the cutting positions “C” by using a slicer or the like. Thereafter, a plurality of individualized wiring boards 1 (see FIG. 1) are completed.

As such, instead of the protection layer 300, the protection layer 310 in which the metal layer 312 is stacked on the adhesive layer 311 may be used. In this case as well, similar to the first embodiment, by forming the protection layer 310, the first pads 12a are prevented from being mechanically damaged (thermal stress or the like) or chemically damaged (thermal oxidation or the like) by heating, or being chemically damaged by the etching solution.

Further, by providing the metal layer 312, mechanical strength of the protection layer 310 becomes higher than that of the protection layer 300. Thus, generation of bending of the structure in the manufacturing step of the wiring board 1 can be reduced. As a result, bending of the completed wiring board 1 can be reduced.

Here, the structure illustrated in FIG. 3D before individualizing may be a completed state for the wiring board 1. In such a case, the wiring board 1 before individualizing is delivered as a product, and a user who obtains the wiring board 1 may mount a semiconductor chip on each of the regions of the wiring board 1 before individualization, and may individualize the regions to manufacture the plurality of semiconductor packages.

### Second Embodiment

In the second embodiment, an example of a semiconductor package in which a semiconductor chip is mounted on the wiring board is exemplified. Here, in the second embodiment, it is to be noted that, in the explanation of the drawings, components same as those described in the above embodiments are given the same reference numerals, and explanations are not repeated. (Structure of semiconductor package of second embodiment)

First, a semiconductor package of the second embodiment is described. FIG. 8A and FIG. 8B are views illustrating an example of semiconductor package 2 of the second embodiment, wherein FIG. 8B is a plan view, and FIG. 8A is a cross-sectional view taken along an A-A line of FIG. 8B.

With reference to FIG. 8A and FIG. 8B, the semiconductor package 2 of the second embodiment includes the wiring board 1, underfill resin 30, a semiconductor chip 40 and connection portions 50.

In the semiconductor package 2, the semiconductor chip 40 is flip-chip mounted in a face-down manner in the openings 21x and 23x that are communicating with each other (in the cavity) of the wiring board 1. The semiconductor chip 40 may be obtained by forming a semiconductor integrated circuit (not illustrated) or the like on a semiconductor substrate 41 that is a thinned silicon or the like, for example. A plurality of electrode pads 42 that are electrically connected to the semiconductor integrated circuit (not illustrated) are formed on the semiconductor substrate 41. Here, a gap may be provided between the inner wall surfaces of the openings 21x and 23x and the side surface of the semiconductor chip 40.

The electrode pads 42 of the semiconductor chip 40 are formed at positions overlapping the first pads 12a of the wiring board 1 in a planar view, respectively.

The electrode pads 42 are electrically connected to the first pads 12a formed at facing positions via the connection portions 50, respectively. The connection portions 50 are, for example, solder bumps. As a material of the solder bump, for example, an alloy containing Pb, an alloy containing Sn and Cu, an alloy containing Sn and Ag, an alloy containing Sn, Ag and Cu and the like may be used.

The underfill resin 30 that covers the electrode pads 42 and the connection portions 50 is filled between the upper surface of the solder resist layer 15 exposed in the opening 21x and a lower surface (circuit forming surface) of the semiconductor chip 40 (facing portions). As the underfill resin 30, for example, insulation resin such as thermosetting epoxy-based resin may be used. The upper surface of the semiconductor chip 40 is exposed in the opening 23x. The upper surface (back surface) of the semiconductor chip 40 and the upper surface of each of the external connection terminals 22 may be flush with each other, for example.

Bumps 60 are formed at the lower surface of the wiring layer 13 that is exposed in the openings 16x of the solder resist layer 16. The bump 60 is, for example, a solder bump. As a material of the bump, for example, an alloy containing an alloy of Pb, an alloy of Sn and Cu, an alloy of Sn and Ag, an alloy of Sn, Ag and Cu and the like may be used. The bumps 60 may be used as external connection terminals to be connected to a mounting substrate such as a mother board.

### (Method of Manufacturing Semiconductor Package of Second Embodiment)

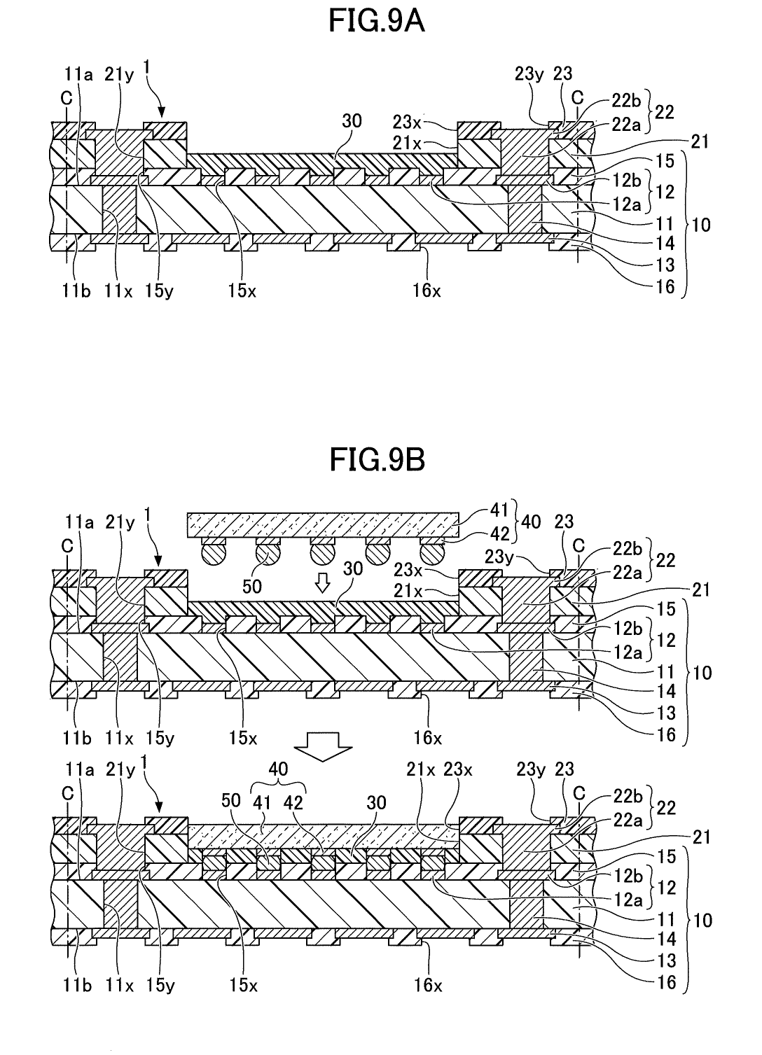

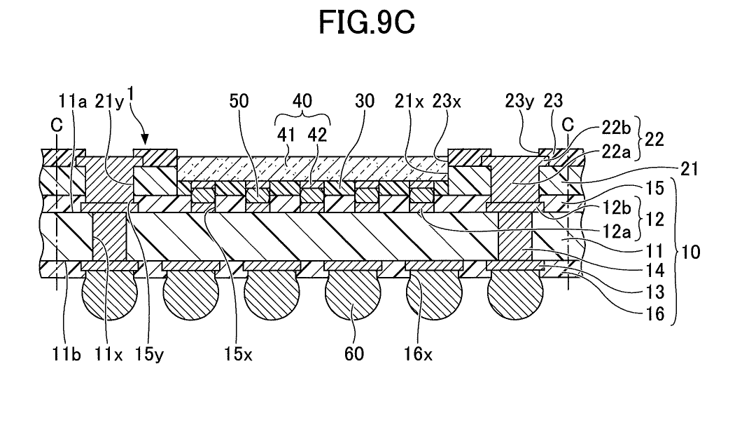

Next, a method of manufacturing the semiconductor package 2 of the second embodiment is described. FIG. 9A to FIG. 9C are views illustrating an example of a manufacturing step of the semiconductor package 2 of the second embodiment. Although an example of a manufacturing step in which semiconductor chips are mounted on a wiring board before being individualized, and a plurality of semiconductor packages are obtained by individualizing the wiring board in this embodiment, a manufacturing step in which a semiconductor chip is mounted on a single wiring board to manufacture a semiconductor package may be alternatively used.

First, in a step illustrated in FIG. 9A, the wiring board 1 is prepared, and liquid or paste underfill resin 30 is coated in the opening 21x to cover the first pads 12a. Alternatively, a film of underfill resin 30 at a B-stage (semi-cured state) may be laminated.

Next, in a step illustrated in FIG. 9B, the semiconductor chip 40 is flip-chip mounted in the openings 21x and 23x that are communicating with each other of the wiring board 1 in a face-down manner. Specifically, for example, the semiconductor chip 40 including the electrode pads 42 and the connection portions 50 formed on the electrode pads 42, respectively, is prepared, and the semiconductor chip 40 is placed by using a chip mounter such that the connection portion 50 side of the semiconductor chip 40 faces the upper surface of the underfill resin 30.

Then, the semiconductor chip 40 is pushed toward the underfill resin 30 under the state that the underfill resin 30 and the connection portions 50 are heated at predetermined temperature. With this, the connection portions 50 penetrate the underfill resin 30 and contact the first pads 12a, respectively. Thereafter, by curing the underfill resin 30 and the connection portions 50, the connection portions 50 are bonded with the first pads 12a, respectively. Further, the underfill resin 30 is filled between the upper surface of the solder resist layer 15 and the lower surface of the semiconductor chip 40 such that to cover the electrode pads 42 and the connection portions 50.

Here, by adjusting the amount of the underfill resin 30, or the pushing force in mounting the semiconductor chip 40, the upper surface of the semiconductor chip 40 and the upper surfaces of the external connection terminals 22 can be made flush with each other.

Next, in a step illustrated in FIG. 9C, the bumps 60 are formed at the lower surface of the wiring layer 13 exposed in the openings 16x of the solder resist layer 16. Specifically, for example, flux is coated on the lower surface of the wiring layer 13 exposed in the openings 16x. Then, the solder balls are mounted, and then reflowed at predetermined temperature. Thereafter, removing the flux by washing the surface, the bumps 60 are formed. Alternatively, a resist layer that exposes regions at which the bumps 60 are to be formed on the lower surface of the solder resist layer 16, and solder paste is printed at the regions exposed from the resist layer. Then, the solder paste is reflowed at predetermined temperature, and thereafter, the flux is removed by washing the surface to form the bumps 60.

After a step illustrated in FIG. 9C, by cutting the structure illustrated in FIG. 9C at the cutting positions “C” by a slicer or the like, a plurality of the individualized semiconductor packages 2 (see FIG. 8A and FIG. 8B) are completed. The step of FIG. 9C can be performed at any desired timing. For example, the step of FIG. 9C may be performed between the step of FIG. 9A and the step of FIG. 9B.

As such, the semiconductor package 2 in which the semiconductor chip 40 is mounted on the wiring board 1 can be actualized. As the wiring board 1 does not include a pattern corresponding to the conductive pattern 12c and the wiring board 1 is small, the semiconductor package 2 can be made smaller.

Further, in a manufacturing step of the wiring board 1, the first pads 12a that are connected to the electrode pads 42 of the semiconductor chip 40 are protected by the protection layer 300 or 310, and the first pads 12a are prevented from being mechanically damaged or chemically damaged. Thus, connection reliability between the first pads 12a and the electrode pads 42 can be improved. In particular, when the protection layer 310 is used, bending of the wiring board 1 is reduced, and connection reliability between the first pads 12a and the electrode pads 42 can be furthermore improved.

Further, by previously conducting an electrical test of the wiring board 1 before the step of FIG. 9A, it is possible to mount the semiconductor chip 40 only on the non-defective wiring board 1 to manufacture the semiconductor package 2. Thus, the semiconductor chip can be prevented from being wasted by mounting the semiconductor chip on the defective wiring board, and manufacturing cost of the semiconductor package can be reduced.

With the above described technique, a wiring board for a semiconductor package having a small size can be provided.

Although a preferred embodiment of the wiring board, the method of manufacturing the wiring board, and the semiconductor package has been specifically illustrated and described, it is to be understood that minor modifications may be made therein without departing from the spirit and scope of the invention as defined by the claims.

The present invention is not limited to the specifically disclosed embodiments, and numerous variations and modifications may be made without departing from the spirit and scope of the present invention.

Various aspects of the subject-matter described herein are set out non-exhaustively in the following numbered clauses:

1. A method of manufacturing a wiring board, including:
preparing a core substrate that includes, at one side of the core substrate, a plurality of first pads for mounting a semiconductor chip, and a plurality of second pads provided at the periphery of the first pads;
forming a protection layer, at the one side of the core substrate, that covers the first pads and exposes the second pads;
forming an insulation layer, at the one side of the core substrate, that covers at least a part of a side surface of the protection layer at a core substrate side, and the second pads, and exposes an upper surface of the protection layer;
forming a plurality of external connection terminals that penetrate the insulation layer, that are electrically connected to the second pads, respectively, and that are partially exposed from an upper surface of the insulation layer; and
removing the protection layer.

2. The method of manufacturing the wiring board according to clause 1,
wherein the protection layer includes an adhesive layer that covers the first pads,
wherein each of the first pads is made of a metal, and
wherein in the removing the protection layer, the adhesive layer is removed by using liquid that dissolves the adhesive layer but does not dissolve the metal.

3. The method of manufacturing the wiring board according to clause 1,
wherein the protection layer includes an adhesive layer that covers the first pads, and a metal layer provided on the adhesive layer,
wherein each of the first pads is made of a metal,
wherein in the removing the protection layer, after removing the metal layer by etching, the adhesive layer is removed by liquid that dissolves the adhesive layer but does not dissolve the metal.

4. The method of manufacturing the wiring board according to clause 3,
wherein the insulation layer includes resin, and
wherein before removing the metal layer by etching, residue of the resin adhered at a surface of the metal layer is removed.

5. The method of manufacturing the wiring board according to clause 1,
wherein in the removing the protection layer, a frame shaped opening that exposes the first pads is formed in the insulation layer, and
wherein a rim of an inner wall surface of the opening at the core substrate side contacts an upper surface of an insulation member of the core substrate.

6. The method of manufacturing the wiring board according to clause 5,
wherein the core substrate includes a solder resist layer that selectively exposes the first pads and the second pads, and
wherein the insulation member is the solder resist layer.

What is claimed is:

1. A wiring board, comprising:
a core substrate that includes, at one side of the core substrate, a plurality of first pads for mounting a semiconductor chip, a plurality of second pads provided at the periphery of the first pads, and a solder resist layer that selectively exposes the first pads and the second pads;
a first insulation layer, formed on an upper surface of the solder resist layer, including an opening to be formed in a frame shape such that to expose the first pads and cover the second pads; and
a plurality of external connection terminals penetrating the first insulation layer to be electrically connected to the second pads exposed from the solder resist layer, respectively, and partially exposed from an upper surface of the first insulation layer,
wherein the core substrate includes a second insulation layer,
wherein the first pads, the second pads and the solder resist layer are directly formed on one surface of the second insulation layer, and
wherein a rim of an inner wall surface of the opening at the core substrate side contacts the upper surface of the solder resist layer.

2. The wiring board according to claim 1,
wherein each of the first pads and the second pads has a circular shape, and
wherein a diameter of each of the first pads is smaller than a diameter of each of the second pads, and also a pitch between the adjacent first pads is smaller than a pitch between the adjacent second pads.

3. The wiring board according to claim 1, wherein the first pads are aligned in an area array form within the opening.

4. The wiring board according to claim 1, wherein the opening has a rectangular planar shape.

5. The wiring board according to claim 1, further comprising:
a wiring layer formed at the other side of the core substrate and including wiring patterns, the other side being opposite of the one side; and
through wirings each penetrating the second insulation layer in a thickness direction of the second insulation layer,
wherein the first pads and the second pads are electrically connected to the wiring patterns of the wiring layer via the through wirings, respectively.

6. The wiring board according to claim 1, wherein the entirety of the upper surface of the solder resist layer including a portion of the upper surface of the solder resist layer that contacts the rim of the inner wall surface of the opening at the core substrate side is flat.

7. A semiconductor package comprising:
the wiring board of claim 1; and
a semiconductor chip including a plurality of electrode pads, and mounted in the opening of the wiring board,
wherein the electrode pads are electrically connected to the first pads via connection portions, respectively.

8. The semiconductor package according to claim 7, further comprising underfill resin provided between surfaces of the solder resist layer and the semiconductor chip, respectively, facing with each other.

9. The semiconductor package according to claim 7, wherein the connection portions are solder bumps.

10. The semiconductor package according to claim 7, wherein an upper surface of the semiconductor chip and an upper surface of each of the external connection terminals are flush with each other.
